(19) United States
(12) Patent Application Publication
(10) Pub. No.: US 2025/0275427 A1
(43) Pub. Date: Aug. 28, 2025

(54) DISPLAY DEVICE

(71) Applicant: LG Display Co., Ltd., Seoul (KR)

(72) Inventors: Jeong-Oh KIM, Paju-si (KR); Myung-Jae YOO, Paju-si (KR); Geum-Young LEE, Paju-si (KR); Jae-Choul YU, Paju-si (KR); Se-Yeon JUNG, Paju-si (KR)

(73) Assignee: LG Display Co., Ltd., Seoul (KR)

(21) Appl. No.: 18/972,384

(22) Filed: Dec. 6, 2024

(30) Foreign Application Priority Data
Feb. 28, 2024 (KR) 10-2024-0028678

(51) Int. Cl. H10K 59/80; H10K 59/121; H10K 59/122; H10K 59/123

(52) U.S. Cl. CPC H10K 59/873; H10K 59/1213; H10K 59/122; H10K 59/123

(57) ABSTRACT

A display device can include a substrate having a contact area and a display area including a plurality of subpixels, a transistor in each of the plurality of subpixels in the display area, a light emitting diode in each of the plurality of subpixels and including a first electrode, an emitting layer and a second electrode, and a first conductive pattern having an opening in the contact area. The emitting layer extends to the first conductive pattern, and the second electrode extends to the first conductive pattern and is electrically connected to a side surface of the first conductive pattern in the opening.

### CROSS REFERENCE TO RELATED APPLICATIONS

The present application claims priority to Korean Patent Application No. 10-2024-0028678, filed in Republic of Korea on Feb. 28, 2024, the entire contents of which is hereby expressly incorporated by reference into the present application.

### BACKGROUND

### Technical Field

The present disclosure relates to a display device, and more particularly, to a display device where a structure of a cathode contact is improved.

### Discussion of the Related Art

Recently, as an information technology is progressed, a flat panel display such as a liquid crystal display (LCD), an organic light emitting diode (OLED) display device, a plasma display panel (PDP) and a micro light emitting diode (LED) display having a small size and a thin profile has been suggested. The flat panel display can be applied to various electronic equipment such as a smart phone and a tablet PC.

The display device includes various layers and various elements such as a display unit displaying an image as well as various electrodes. When moisture permeates into the display device from an exterior, the electrodes can be corroded or the organic layer can be deteriorated.

The moisture permeation can occur in various regions. For example, the moisture can permeate into the display device due to a crack generated in a cathode contact area for applying a low level voltage to a light emitting diode.

### SUMMARY OF THE DISCLOSURE

Accordingly, the present disclosure is directed to a display device that substantially obviates one or more of the problems due to limitations and disadvantages of the related art.

An object of the present disclosure is to provide a display device where moisture permeation due to a crack in a cathode contact area is prevented.

Additional features and advantages of the disclosure will be set forth in the description which follows, and in part will be apparent from the description, or can be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes a substrate having a contact area and a display area including a plurality of subpixels; a transistor in each of the plurality of subpixels in the display area; a light emitting diode in each of the plurality of subpixels and including a first electrode, an emitting layer and a second electrode; and a first conductive pattern having an opening in the contact area, wherein the emitting layer extends to the first conductive pattern, and wherein the second electrode extends to the first conductive pattern and is electrically connected to a side surface of the first conductive pattern in the opening.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this disclosure, illustrate embodiments of the disclosure and together with the description serve to explain the principles of the disclosure. In the drawings:

FIG. 1 is a view showing a display device according to a first embodiment of the present disclosure;

FIG. 2 is a view showing a subpixel of the display device according to the first embodiment of the present disclosure;

FIG. 3 is a circuit diagram showing the subpixel of the display device according to the first embodiment of the present disclosure;

FIG. 4 is a plan view showing the display device according to the first embodiment of the present disclosure;

FIG. 5 is a magnified view showing a portion A of FIG. 4;

FIG. 6 is a cross-sectional view showing the display device according to the first embodiment of the present disclosure;

FIGS. 7A to 7F are cross-sectional views showing a method of fabricating the display device according to the first embodiment of the present disclosure; and

FIG. 8 is a cross-sectional view showing a contact area of a display device according to a second embodiment of the present disclosure.

### DETAILED DESCRIPTION OF THE EMBODIMENTS

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the disclosure, unless otherwise specified.

In the following description, where the detailed description of the relevant known function or configuration can unnecessarily obscure a feature or aspect of the present disclosure, a detailed description of such known function or configuration can be omitted or a brief description can be provided.

Where the terms “comprise,” “have,” “include,” and the like are used, one or more other elements can be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third layer or element can be interposed therebetween.

Although the terms “first,” “second,” A, B, (a), (b), and the like can be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” can include all combinations of two or more of the first, second and third elements as well as the first, second or third element.

The term “display device” can include a display device in a narrow sense such as liquid crystal module (LCM), an organic light emitting diode (OLED) module and a quantum dot (QD) module including a display panel and a driving unit for driving the display panel. In addition, the term “display device” can include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure can include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit can be expressed as “a display device”, and an electronic apparatus of a complete product including the LCM, the OLED module and the QD module can be expressed as “a set device.” For example, a display device in a narrow sense can include a display panel of a liquid crystal, an organic light emitting diode and a quantum dot and a source printed circuit board (PCB) of a control unit for driving the display panel, and a set device can further include a set PCB of a set control unit electrically connected to the source PCB for controlling the entire set device.

The display panel of the present disclosure can include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel can include a plurality of gate lines, a plurality of data lines and a subpixel in a crossing region of the plurality of gate lines and the plurality of data lines. The display panel can include an array having a thin film transistor of an element for selectively applying a voltage to each subpixel, an emitting element layer on the array and an encapsulating substrate or an encapsulation part covering the emitting element layer. The encapsulation part can protect the thin film transistor and the emitting element layer from an external impact and can prevent or at least reduce penetration of moisture or oxygen into the emitting element layer. In addition, a layer on the array can include an inorganic light emitting layer, for example, a nano-sized material layer or a quantum dot.

The thin film transistor of the present disclosure can include one of an oxide thin film transistor, an amorphous silicon thin film transistor, a low temperature polycrystalline silicon thin film transistor.

Features of various embodiments of the present disclosure can be partially or entirely coupled to or combined with each other. They can be linked and operated technically in various ways as those skilled in the art can sufficiently understand. The embodiments can be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

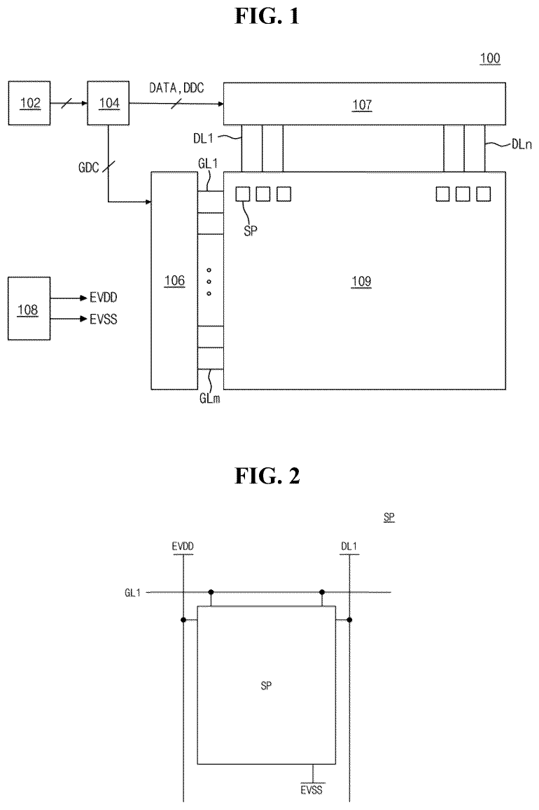

FIG. 1 is a view showing a display device according to a first embodiment of the present disclosure, and FIG. 2 is a view showing a subpixel of the display device according to the first embodiment of the present disclosure.

In FIG. 1, a display device 100 according to the first embodiment of the present disclosure includes an image processing unit 102, a timing controlling unit 104, a gate driving unit 106, a data driving unit 107, a power supplying unit 108 and a display panel 109.

The image processing unit 102 outputs a plurality of timing signals for various units as well as an image signal supplied from an exterior. For example, the plurality of timing signals can include a data enable signal, a vertical synchronization signal, a horizontal synchronization signal and a clock signal.

The timing controlling unit 104 receives the image signal and the plurality of timing signals from the image processing unit 102. The timing controlling unit 104 generates an image data DATA, a gate control signal GDC and a data control signal DDC using the image signal and the plurality of timing signals. The timing controlling unit 104 transmits the gate control signal GDC to the gate driving unit 106 and transmits the image data and the data control signal DDC to the data driving unit 107.

The gate driving unit 106 generates a gate signal (a gate voltage, a scan signal) using the gate control signal GDC transmitted from the timing controlling unit 104 and applies the gate signal to a plurality of gate lines GL1 to GLm of the display panel 109. Although the gate driving unit 106 can be formed as an integrated circuit (IC), it is not limited thereto. The gate driving unit 106 can have a gate-in-panel (GIP) type where the gate driving unit 106 is disposed on a substrate of the display panel 109.

The data driving unit 107 generates a data signal (a data voltage) using the data control signal DDC and the image data DATA transmitted from the timing controlling unit 104 and applies the data signal to a plurality of data lines DL1 to DLn of the display panel 109. The data driving unit 107 samples and latches the image data DATA of a digital type to output the data signal of an analog type based on a gamma reference voltage. Although the data driving unit 107 can be formed as an integrated circuit (IC), it is not limited thereto.

The power supplying unit 108 outputs a high level voltage Vdd and a low level voltage Vss. The power supplying unit 108 supplies the high level voltage Vdd to the display panel 109 through a first power line EVDD and supplies the low level voltage Vss to the display panel 109 through a second power line EVSS. In addition, the high level voltage Vdd and the low level voltage Vss of the power supplying part 108 can be supplied to the gate driving unit 106 or the data driving unit 107 for driving.

The display panel 109 displays an image using the gate signal of the gate driving unit 106, the data signal of the data driving unit 107 and the high level voltage Vdd and the low level voltage Vss of the power supplying unit 108.

The display panel 109 includes a plurality of subpixels SP, a plurality of gate lines GL1 to GLm and a plurality of data lines DL1 to DLn. The plurality of subpixels SP can include red, green and blue subpixels SP or white, red, green and blue subpixels SP. The white, red, green and blue subpixels SP can have the same area as each other or can have a different area from each other.

In FIG. 2, a single subpixel SP can be connected to the gate line GL1, the data line DL1, the first power line EVDD and the second power line EVSS. A driving method as well as a number of a transistor and a capacitor of the subpixel SP can be determined according to a structure of a subpixel circuit. For example, the subpixel SP can have a structure of 2T1C including two transistors and one capacitor. In another embodiment, the subpixel SP can have a structure of one of 3T1C, 4T1C, 5T1C, 6TIC, 7TIC, 3T2C, 4T2C, 5T2C, 6T2C, 7T2C and 8T2C.

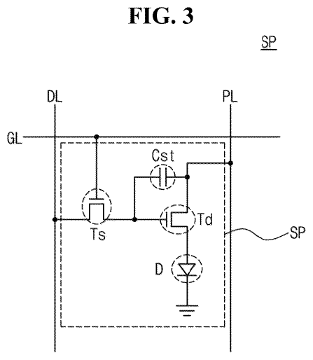

FIG. 3 is a circuit diagram showing a subpixel of the display device according to the first embodiment of the present disclosure.

In FIG. 3, the display device 100 includes the gate line GL, the data line DL and the power line PL crossing each other to define the subpixel SP. A switching transistor Ts, a driving transistor Td, a storage capacitor Cst and a light emitting diode D are disposed in the subpixel SP.

The switching transistor Ts is connected to the gate line GL and the data line DL. The driving transistor Td and the storage capacitor Cst are connected between the switching transistor Ts and the power line PL. The light emitting diode D is connected to the driving transistor Td.

When the switching transistor Ts is turned on according to the gate signal of the gate line GL, the data signal of the data line DL is applied to a gate electrode of the driving transistor Td and one capacitor electrode of the storage capacitor Cst through the switching transistor Ts.

Since the driving transistor Td is turned on according to the data signal, a current proportional to the data signal flows from the power line PL to the light emitting diode D through the driving transistor Td and the light emitting diode D emits a light of a luminance proportional to the current flowing through the driving transistor Td.

The storage capacitor Cst is charged up with a voltage proportional to the data signal to keep a voltage of the gate electrode of the driving transistor Td constant for one frame.

Although the subpixel SP includes two transistors Ts and Td and one capacitor Cst in the first embodiment of FIG. 3, the subpixel SP can include three or more transistors and two or more capacitors in another embodiment.

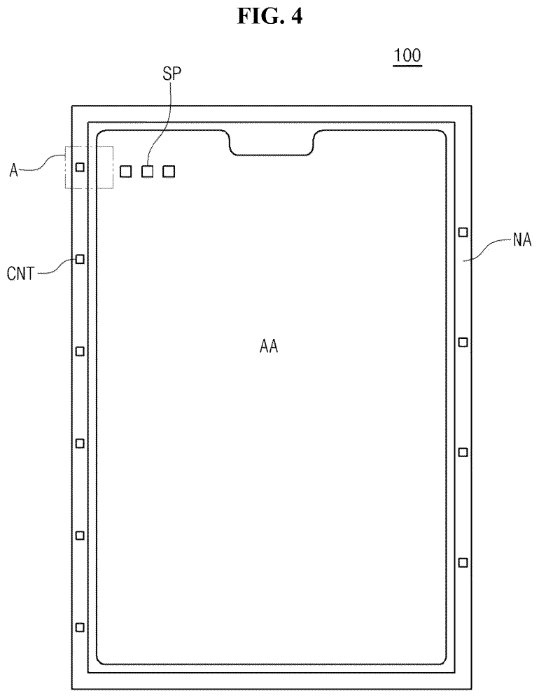

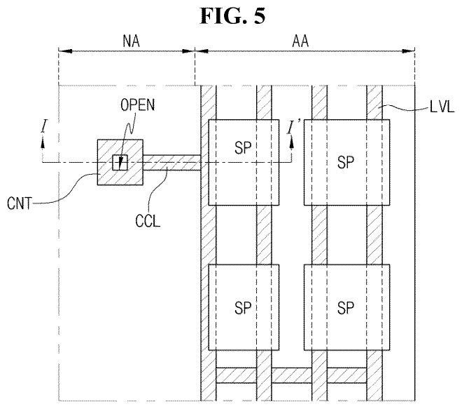

FIG. 4 is a plan view showing the display device according to the first embodiment of the present disclosure, and FIG. 5 is a magnified view showing a portion A of FIG. 4.

In FIGS. 4 and 5, the display device 100 according to the first embodiment of the present disclosure includes a display area AA (or active area) and a non-display area NA (or non-active area) surrounding the display area AA. The non-display area NA can surround the display area AA entirely or only in part(s).

A plurality of subpixels SP are disposed in the display area AA. The plurality of subpixels SP can include a red subpixel, a green subpixel and a blue subpixel. The plurality of subpixels SP can further include a white subpixel.

The plurality of gate lines GL and the plurality of data lines DL are disposed in the display area AA, and each subpixel SP is disposed in a region where the gate line GL and the data line DL cross each other. A thin film transistor as a switching element and a displaying unit displaying a real image are disposed in each subpixel SP.

The displaying unit can include various elements. For example, the displaying unit can include an organic light emitting diode, a liquid crystal capacitor, a quantum dot, a micro light emitting diode and a mini light emitting diode.

The gate driving unit 106 and the data driving unit 107 supplying the gate signal and the data signal to the plurality of subpixels SP are disposed in the non-display area NA. The gate driving unit 106 supplies the gate signal to the plurality of subpixels SP through the gate line GL, and the data driving unit 107 supplies the data signal to the plurality of subpixels SP through the data line DL.

A low level voltage line LVL is disposed in the display area AA. The low level voltage line LVL is connected to the light emitting diode D of each subpixel SP to supply the low level voltage Vss to the cathode of the light emitting diode D. Although two low level voltage lines LVL are disposed to correspond to one subpixel column in the first embodiment of FIG. 5, one low level voltage line LVL can be disposed to correspond to one subpixel column in another embodiment. Further, the low level voltage line LVL can have a dummy shape to be disposed in the entire display area AA as one body together with the cathode.

A contact area CNT and a connecting line CCL are disposed in the non-display area NA. The connecting line CCL connects the contact area CNT and the low level voltage line LVL to supply the low level voltage Vss to the light emitting diode D.

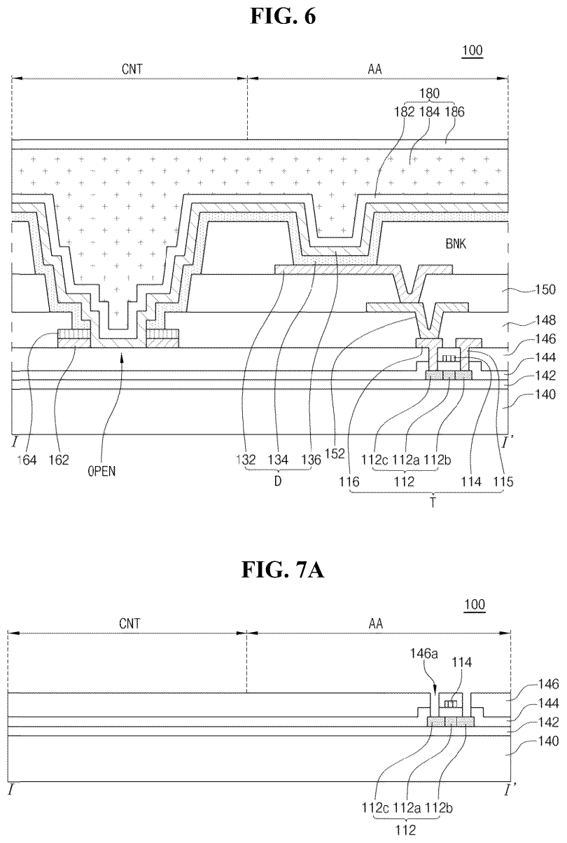

FIG. 6 is a cross-sectional view showing the display device according to the first embodiment of the present disclosure. Particularly, FIG. 6, which is taken along a line I-I′ of FIG. 5, shows the subpixel SP of the display area AA and the contact area CNT of the non-display area NA.

In FIG. 6, a substrate 140 has the display area AA and the contact area CNT. The substrate 140 can include a hard material such as a glass or a soft material such as a plastic material.

The plastic material can include polyimide (PI), polymethylmethacrylate (PMMA), polyethylene terephthalate (PET), polyether sulfone (PES) and polycarbonate (PC), and it is not limited thereto.

For example, when the substrate 140 includes polyimide, the substrate 140 can include a plurality of polyimide layers. Further, an inorganic layer can be disposed between the polyimide layers, and it is not limited thereto.

A buffer layer 142 is disposed on the substrate 140. The buffer layer 142 can be disposed on the entire substrate 140 to increase an adhesive strength between layers and the substrate 140 and to block an alkali ingredient released from the substrate 140. Further, the buffer layer 142 can delay diffusion of moisture or oxygen permeating the substrate 140.

The buffer layer 142 can have a single layer or a multiple layer of an inorganic insulating material such as silicon nitride (SiNx) and silicon oxide (SiOx). When the buffer layer 142 has a multiple layer, a layer of silicon nitride (SiNx) and a layer of and silicon oxide (SiOx) can be alternated with each other. The buffer layer 142 can be omitted based on a kind and a material of the substrate 140 and a structure and a type of the thin film transistor.

A thin film transistor T is disposed on the buffer layer 142 in the display area AA. Although a driving thin film transistor among a plurality of thin film transistors is shown in FIG. 6, the other thin film transistors such as a switching thin film transistor can be disposed on the buffer layer 142. Further, although the thin film transistor T has a top gate structure in the first embodiment of FIG. 6, the thin film transistor T can have the other structure such as a bottom gate structure in another embodiment.

The thin film transistor T includes a semiconductor layer 112 on the buffer layer 142, a gate insulating layer 144 on the semiconductor layer 112, a gate electrode 114 on the gate insulating layer 144, an interlayer insulating layer 146 on the gate electrode 114 and source and drain electrodes 115 and 116 on the interlayer insulating layer 146.

The semiconductor layer 112 can include a polycrystalline semiconductor material. For example, the polycrystalline semiconductor material can include polycrystalline silicon having a relatively high mobility, and it is not limited thereto.

The semiconductor layer 112 can include an oxide semiconductor material. For example, the oxide semiconductor material can include one of indium gallium zinc oxide (IGZO), indium zinc oxide (IZO), indium gallium tin oxide (IGTO) and indium gallium oxide (IGO), and it is not limited thereto. The semiconductor layer 112 has a channel region 112a of an intrinsic material at a central portion thereof and source and drain regions 112b and 112c of a doped material at both sides of the channel region 112a.

The gate insulating layer 144 can be disposed in the display area AA and the contact area CNT or only in the display area AA. The gate insulating layer 144 can have a single layer or a multiple layer of an inorganic insulating material such as silicon nitride (SiNx) and silicon oxide (SiOx), and it is not limited thereto.

The gate electrode 114 includes a metallic material. For example, the gate electrode 114 can have a single layer or a multiple layer of one of molybdenum (Mo), aluminum (Al), chromium (Cr), gold (Au), silver (Ag), tungsten (W), titanium (Ti), nickel (Ni), neodymium (Nd), copper (Cu) and an alloy thereof, and it is not limited thereto.

The interlayer insulating layer 146 can be disposed in the display area AA and the contact area CNT or only in the display area AA. The interlayer insulating layer 146 can have a single layer or a multiple layer of an organic insulating material such as photoacryl or an inorganic insulating material such as silicon nitride (SiNx) and silicon oxide (SiOx). Further, the interlayer insulating layer 146 can have a multiple layer of an organic layer and an inorganic layer, and it is not limited thereto.

The source and drain electrodes 115 and 116 can have a single layer or a multiple layer of one of molybdenum (Mo), aluminum (Al), chromium (Cr), gold (Au), silver (Ag), tungsten (W), titanium (Ti), nickel (Ni), neodymium (Nd), copper (Cu) and an alloy thereof, and it is not limited thereto. The source and drain electrodes 115 and 116 can be connected to the source and drain regions 112b and 112c, respectively, of the semiconductor layer 112 through contact holes in the gate insulating layer 144 and the interlayer insulating layer 146.

A bottom shielding metal layer can be disposed on the substrate 140 under the semiconductor layer 112. The bottom shielding metal layer can minimize a back channel phenomenon generated due to charges trapped in the substrate 140 to prevent a residual image or deterioration of a transistor. The bottom shielding metal layer can have a single layer or a multiple layer of one of titanium (Ti), molybdenum (Mo) and an alloy thereof, and it is not limited thereto.

A first planarizing layer 148 is disposed on the thin film transistor T over the substrate 140. The first planarizing layer 148 can include an organic insulating material such as photoacryl or an inorganic insulating material such as silicon nitride (SiNx) and silicon oxide (SiOx), and it is not limited thereto. The first planarizing layer 148 can have a multiple layer of an inorganic layer and an organic layer.

A connecting electrode 152 is disposed on the first planarizing layer 148. The connecting electrode 152 can include at least one of silver (Ag), aluminum (Al), gold (Au), molybdenum (Mo), tungsten (W), copper (Cu) and an alloy thereof, and it is not limited thereto. The connecting electrode 152 is electrically connected to the drain electrode 116 of the thin film transistor T through a contact hole in the first planarizing layer 148.

A second planarizing layer 150 is disposed on the connecting layer 152 over the first planarizing layer 148. The second planarizing layer 150 can include an organic insulating material such as photoacryl or an inorganic insulating material such as silicon nitride (SiNx) and silicon oxide (SiOx), and it is not limited thereto. The second planarizing layer 150 can have the same material as or the different material from the first planarizing layer 148.

The second planarizing layer 150 can include a photosensitive material including a black pigment.

A light emitting diode D is disposed on the second planarizing layer 150 in the display area AA. The light emitting diode D includes a first electrode 132, an emitting layer 134 and a second electrode 136.

The first electrode 132 is disposed on the second planarizing layer 150 and is electrically connected to the connecting electrode 152 through a contact hole in the second planarizing layer 150. The first electrode 132 can be electrically connected to the drain electrode 116 of the thin film transistor T through the connecting electrode 152.

Since the planarizing layer has a multiple layer, various electrodes and various lines can be disposed between the plurality of planarizing layers as a vertical structure. Since a degree of integration of the electrodes and the lines increases, an area for the electrodes and the lines in the subpixel SP is reduced to obtain the display device 100 of a high resolution.

In another embodiment, the second planarizing layer 150 can be omitted and only the first planarizing layer 148 can be disposed according to a structure of the display device 100.

The first electrode 132 can include at least one of silver (Ag), aluminum (Al), gold (Au), molybdenum (Mo), tungsten (W), chromium (Cr) and an alloy thereof. Alternatively, the first electrode 132 can include a transparent conductive material such as indium tin oxide (ITO) and indium zinc oxide (IZO).

When the display device 100 has a top emission type, the first electrode 132 can further include an opaque conductive material for using the first electrode 132 as a reflective layer. When the display device 100 has a bottom emission type, the first electrode 132 can include a transparent conductive material such as indium tin oxide (ITO) and indium zinc oxide (IZO).

A bank layer BNK is disposed in a boundary region of each subpixel on the second planarizing layer 150. The bank layer BNK can be a kind of wall defining the subpixel. The bank layer BNK can prevent a mixture of lights of various colors emitted from adjacent subpixels SP.

The bank layer BNK can include at least one of an inorganic insulating material such as silicon nitride (SiNx) and silicon oxide (SiOx), an organic insulating material such as benzocyclobutene (BCB), acrylic resin, epoxy resin, phenolic resin, polyamide resin and polyimide resin and a photosensitive material including a black pigment, and it is not limited thereto.

The emitting layer 134 can be disposed on a top surface of the first electrode 132, a side surface of the bank layer BNK and a top surface of the bank layer BNK and can extend to the contact area CNT.

The emitting layer 134 can include a red emitting layer emitting a red colored light in a red subpixel SP, a green emitting layer emitting a green colored light in a green subpixel SP and a blue emitting layer emitting a blue colored light in a blue subpixel SP. For example, the emitting layer 134 can include an organic emitting layer, an inorganic emitting layer, a nano-sized material layer, a quantum dot layer, an emitting layer of a micro light emitting diode (LED) and an emitting layer of a mini LED, and it is not limited thereto.

The emitting layer 134 can include an emitting material layer, an electron injecting layer injecting an electron, a hole injecting layer injecting a hole, an electron transporting layer transporting an electron, a hole blocking layer blocking a hole, an electron blocking layer blocking an electron and a hole transporting layer transporting a hole, and it is not limited thereto.

The second electrode 136 is disposed on the emitting layer 134. The second electrode 136 can have a single layer or a multiple layer of a metallic material or an alloy of metallic materials. Alternatively, the second electrode 136 can include a transparent conductive material such as indium tin oxide (ITO) and indium zinc oxide (IZO), and it is not limited thereto.

When the display device 100 has a top emission type, the second electrode 136 can include a half transmissive conductive material transmitting a light. For example, the second electrode 136 can include at least one of alloys of LiF/Al, CsF/Al, Mg:Ag, Ca/Ag, Ca:Ag, LiF/Mg:Ag, LiF/Ca/Ag and LiF/Ca:Ag.

When the display device 100 has a bottom emission type, the second electrode 136 can include an opaque conductive material for using the second electrode 136 as a reflective layer. For example, the second electrode 136 can include at least one of silver (Ag), aluminum (Al), gold (Au), molybdenum (Mo), tungsten (W), chromium (Cr) and an alloy thereof.

The light emitting diode D can have a tandem structure. The tandem structure can include a plurality of emitting layers and a charge generating layer between adjacent two of the plurality of emitting layers. The charge generating layer for adjusting a charge balance of the plurality of emitting layers can have a multiple layer including first and second charge generating layers. The charge generating layer can include a negative (N) type charge generating layer and a positive (P) type charge generating layer. For example, the charge generating layer can include an organic layer doped with an alkali metal such as lithium (Li), sodium (Na), potassium (K) and cesium (Cs) or an alkali earth metal such as magnesium (Mg), strontium (Sr), barium (Ba) and radium (Ra), and it is not limited thereto.

A first conductive pattern 162 having an opening OPEN and connected to the power supplying unit 108 is disposed on the interlayer insulating layer 146 in the contact area CNT. Although the opening OPEN has a rectangular shape in the first embodiment of FIG. 5, the opening OPEN can have a polygonal shape such as triangular shape, a pentagonal shape and a hexagonal shape, a circular shape or an elliptical shape in another embodiment.

The first conductive pattern 162 can be formed through the same process as the source and drain electrodes 115 and 116 to have the same metallic material as the source and drain electrodes 115 and 116, and it is not limited thereto.

A second conductive pattern 164 having the opening OPEN is disposed on the first conductive pattern 162. An end portion of the opening OPEN of the second conductive pattern 164 coincides with an end portion of the opening OPEN of the first conductive pattern 162. The second conductive pattern 164 can include a transparent conductive material such as indium tin oxide (ITO) and indium zinc oxide (IZO), and it is not limited thereto.

The second conductive pattern 164 prevents oxidation or corrosion of the first conductive pattern 162 while the opening OPEN is formed. The second conductive pattern 164 can be used for removing the emitting layer 134 in the opening OPEN without using an additional photomask.

Although the first conductive pattern 162 is disposed on the interlayer insulating layer 146 with the same material as the source and drain electrodes 115 and 116 in the first embodiment of FIG. 6, the first conductive pattern 162 can be disposed on the first planarizing layer 148 with the same material as the connecting electrode 152 in another embodiment.

The first planarizing layer 148 having the opening OPEN is disposed on the first and second conductive patterns 162 and 164 in the contact area CNT. An end portion of the opening OPEN of the first planarizing layer 148 is spaced apart from the end portion of the opening OPEN of the first and second conductive patterns 162 and 164. As a result, the first planarizing layer 148 and the first and second conductive patterns 162 and 164 constitute a step difference in the opening OPEN.

The second planarizing layer 150 having the opening OPEN is disposed on the first planarizing layer 148 in the contact area CNT. An end portion of the opening OPEN of the second planarizing layer 150 is spaced apart from the end portion of the opening OPEN of the first planarizing layer 148. As a result, the second planarizing layer 150 and the first planarizing layer 148 constitute a step difference in the opening OPEN.

The bank layer BNK having the opening OPEN is disposed on the second planarizing layer 150 in the contact area CNT. An end portion of the opening OPEN of the bank layer BNK is spaced apart from the end portion of the opening OPEN of the second planarizing layer 150. As a result, the bank layer BNK and the second planarizing layer 150 constitute a step difference in the opening OPEN.

Since the opening constituted by the first conductive pattern 162, the second conductive pattern 164, the first planarizing layer 148, the second planarizing layer 150 and the bank layer BNK has the gradual step differences, a diameter of the opening OPEN increases from the first conductive pattern 162 to the bank layer BNK.

The emitting layer 134 of the light emitting diode D in the display area AA extends to the contact area CNT. The emitting layer 134 is disposed on the second conductive pattern 164 in the contact area CNT and is not disposed in the opening OPEN.

The second electrode 136 of the light emitting diode D in the display area AA extends to the contact area CNT. The second electrode 136 is disposed on the interlayer insulating layer 146 exposed through the opening OPEN as well as on the step differences of the first conductive pattern 162, the second conductive pattern 164, the first planarizing layer 148, the second planarizing layer 150 and the bank layer BNK in the opening OPEN.

As a result, the second electrode 136 electrically contacts side surfaces of the first and second contact patterns 162 and 164 such that the low level voltage Vss of the power supplying unit 108 is supplied to the second electrode 136 through the first and second conductive patterns 162 and 164.

An encapsulating layer 180 is disposed on the second electrode 136 of the light emitting diode D in the display area AA and the contact area CNT. When the light emitting diode D is exposed to moisture or oxygen, a pixel shrinkage phenomenon where an emission area EA is reduced or deterioration of a dark spot in the emission area EA can occur. Further, moisture or oxygen can oxidize the electrode of a metallic material. The encapsulating layer 180 blocks permeation of moisture or oxygen from an exterior to prevent deterioration of the light emitting diode D and the electrodes.

Although the encapsulating layer 180 has a triple layer of first, second and third encapsulating layers 182, 184 and 186 in the first embodiment, the encapsulating layer 180 can have a double layer or a quadruple layer in another embodiment.

The first and third encapsulating layer 182 and 186 can have a single layer or a multiple layer of an inorganic material such as silicon oxide (SiOx), silicon oxynitride (SiON) and silicon nitride (SiNx), and it is not limited thereto. The second encapsulating layer 184 can include an organic material such as acryl resin, epoxy resin, polyimide, polyethylene and silicon oxycarbide (SiOC), and it is not limited thereto. The third encapsulating layer 186 can include a face seal metal, and it is not limited thereto.

The display device 100 can include a touch unit. The touch unit can be disposed in the display area AA to sense a touch input. For example, the touch unit can sense an external touch information using a finger of a user or a touch pen.

In the display device 100 according the first embodiment of the present disclosure, since the first conductive pattern 162, the second conductive pattern 164, the first planarizing layer 148, the second planarizing layer 150 and the bank layer BNK constitute step differences in the contact area CNT, a crack of the second electrode 136 in the contact area CNT due to a reverse step difference or an overhang is prevented. As a result, permeation of moisture due to a crack is prevented.

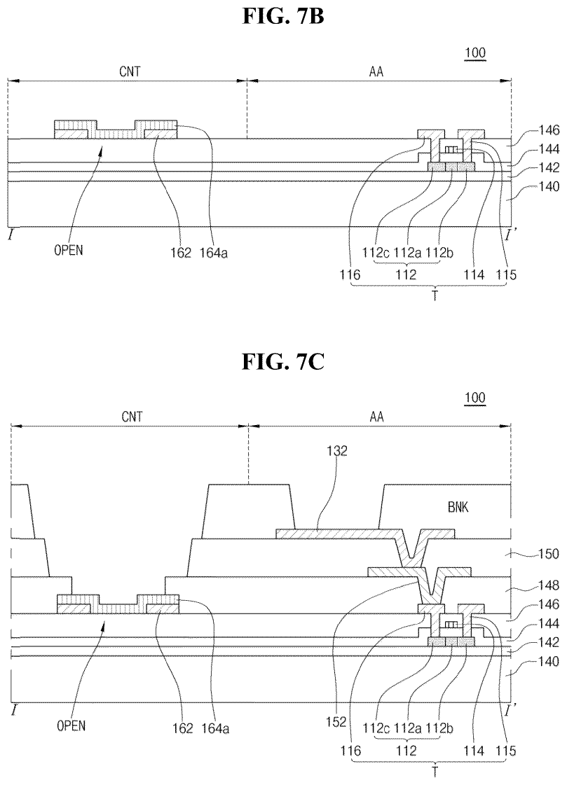

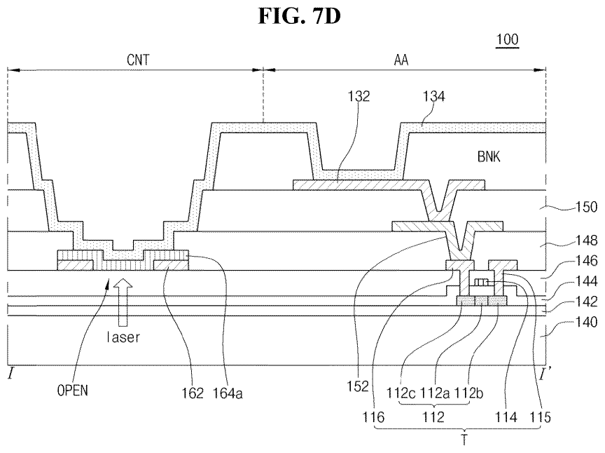

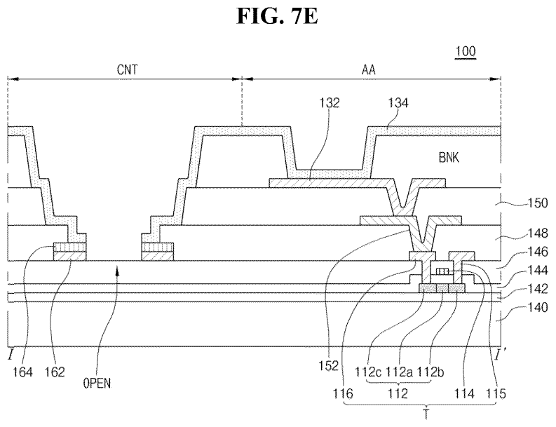

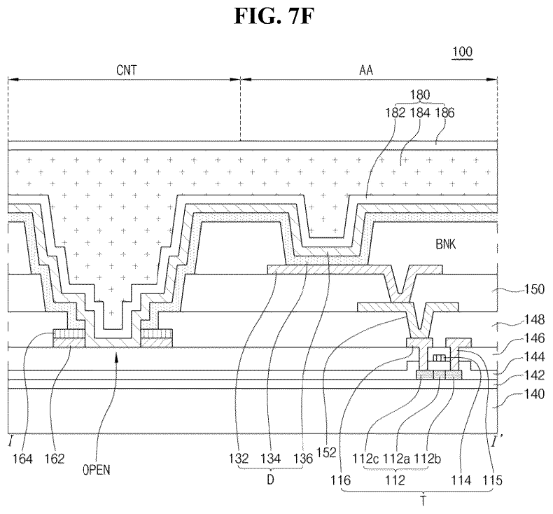

FIGS. 7A to 7F are cross-sectional views showing a method of fabricating the display device according to the first embodiment of the present disclosure.

In FIG. 7A, the buffer layer 142 is formed on the entire substrate 140 having the display area AA and the contact area CNT. The substrate 140 can include a hard material such as a glass or a soft material such as a plastic material. The plastic material can include polyimide (PI), polymethylmethacrylate (PMMA), polyethylene terephthalate (PET), polyether sulfone (PES) and polycarbonate (PC). The buffer layer 142 can have a single layer or a multiple layer of an inorganic insulating material such as silicon nitride (SiNx) and silicon oxide (SiOx).

Next, the semiconductor layer 112 is formed on the buffer layer 142 by depositing and patterning a polycrystalline semiconductor material such as polycrystalline silicon or an oxide semiconductor material such as indium gallium zinc oxide (IGZO), indium zinc oxide (IZO), indium gallium tin oxide (IGTO) and indium gallium oxide (IGO). Next, the channel region 112a, the source region 112b and the drain region 112c are formed by doping the side portions of the semiconductor layer 112 with an impurity.

Next, the gate insulating layer 144 is formed on the semiconductor layer 112 by depositing an inorganic insulating material such as silicon nitride (SiNx) and silicon oxide (SiOx). Next, the gate electrode 114 is formed on the gate insulating layer 144 by depositing and patterning a metallic material such as molybdenum (Mo), aluminum (Al), chromium (Cr), gold (Au), silver (Ag), tungsten (W), titanium (Ti), nickel (Ni), neodymium (Nd) and copper (Cu). For example, the metallic material can be deposited through a sputtering method, and the metallic material layer can be etched through a wet etching method.

Next, the interlayer insulating layer 146 is formed on the gate electrode 114 by depositing an organic insulating material such as photoacryl or an inorganic insulating material such as silicon nitride (SiNx) and silicon oxide (SiOx). Next, contact holes exposing the source and drain regions 112b and 112c of the semiconductor layer 112 are formed in the interlayer insulating layer 146 and the gate insulating layer 144 by patterning the interlayer insulating layer 146 and the gate insulating layer 144. For example, the interlayer insulating layer 146 and the gate insulating layer 144 can be etched through a dry etching method.

In FIG. 7B, the source and drain electrodes 115 and 116 are formed on the interlayer insulating layer 146 in the display area AA and the first conductive pattern 162 is formed on the interlayer insulating layer 146 in the contact area CNT by depositing and patterning a metallic material such as molybdenum (Mo), aluminum (Al), chromium (Cr), gold (Au), silver (Ag), tungsten (W), titanium (Ti), nickel (Ni), neodymium (Nd) and copper (Cu). For example, the metallic material can be deposited through a sputtering method and can be etched through a wet etching method. The source and drain electrodes 115 and 116 are electrically connected to the source and drain regions 112b and 112c, respectively, of the semiconductor layer 112 through contact holes, and the first conductive pattern 162 has the opening OPEN. The semiconductor layer 112, the gate electrode 114, the source electrode 115 and the drain electrode 116 constitute the thin film transistor T.

Next, a conductive layer 164a is formed on the first conductive pattern 162 by depositing and patterning a transparent conductive material such as indium tin oxide (ITO) and indium zinc oxide (IZO). The conductive layer 164a is disposed on the first conductive pattern 162 and the interlayer insulating layer 146 exposed through the opening OPEN of the first conductive pattern 162. Since the conductive layer 164a is disposed on the first conductive pattern 162, oxidation or corrosion of the first conductive pattern 162 during a process is prevented.

In FIG. 7C, the first planarizing layer 148 is formed on the source and drain electrodes 115 and 116 and the conductive layer 164a by depositing at least one of an organic material such as photoacryl or an inorganic material such as silicon oxide (SiOx) and silicon nitride (SiNx). Next, a contact hole exposing the drain electrode 116 and the opening OPEN exposing the conductive layer 164a are formed by patterning the first planarizing layer 148. For example, the first planarizing layer 148 can be etched through a dry etching method.

Next, the connecting electrode 152 is formed on the first planarizing layer 148 by depositing and patterning a metallic material such as molybdenum (Mo), aluminum (Al), chromium (Cr), gold (Au), silver (Ag), tungsten (W), titanium (Ti), nickel (Ni), neodymium (Nd) and copper (Cu). The connecting electrode 152 is electrically connected to the drain electrode 116 of the thin film transistor T through the contact hole in the first planarizing layer 148.

Next, the second planarizing layer 150 is formed on the connecting electrode 152 by depositing an organic material such as photoacryl or a photosensitive material including a black pigment. Next, a contact hole exposing the connecting electrode 152 and the opening OPEN exposing the conductive layer 164a are formed by patterning the second planarizing layer 150. For example, the second planarizing layer 150 can be etched through a dry etching method.

Next, the first electrode 132 is formed on the second planarizing layer 150 by depositing and patterning a metallic material such as silver (Ag), aluminum (Al), gold (Au), molybdenum (Mo), tungsten (W), chromium (Cr) and an alloy thereof or a transparent conductive material such as indium tin oxide (ITO) and indium zinc oxide (IZO). For example, the metallic material or the transparent conductive material can be deposited through a sputtering method and can be etched through a wet etching method. Since the first electrode 132 is electrically connected to the connecting electrode 152 through the contact hole in the second planarizing layer 150, the first electrode 132 is electrically connected to the drain electrode 116 of the thin film transistor T through the connecting electrode 152.

Next, the bank layer BNK is formed on the first electrode 132 and the second planarizing layer 150 by depositing and patterning an inorganic insulating material such as silicon nitride (SiNx) and silicon oxide (SiOx), an organic insulating material such as benzocyclobutene (BCB), acrylic resin, epoxy resin, phenolic resin, polyamide resin and polyimide resin or a photosensitive material including a black pigment. The bank layer BNK has an open portion exposing the first electrode 132 and the opening OPEN exposing the conductive layer 164a.

In FIG. 7D, the emitting layer 134 is formed on the first electrode 132 in the display area AA and the conductive layer 164a in the contact area CNT by depositing an organic emitting material. Next, a laser is irradiated onto the conductive layer 164a in the opening OPEN from a portion under the substrate 140. A heat is generated in the conductive layer 164a due to the laser absorbed by the conductive layer 164a, and the conductive layer 164a and the emitting layer 134 are evaporated.

In FIG. 7E, portions of the conductive layer 164a and the emitting layer 134 corresponding to the opening OPEN of the first conductive pattern 162 are removed by the laser irradiation. As a result, the second conductive pattern 164 having the opening OPEN is formed on the first conductive pattern 162, and the emitting layer having the opening OPEN is formed on the second conductive pattern 164.

When the second planarizing layer 150 and the bank layer BNK are formed of a photosensitive material including a black pigment, the second planarizing layer 150 and the bank layer BNK as a laser blocking layer can block the laser irradiated onto the conductive layer 164a in the opening OPEN. Since the laser is not irradiated onto the emitting layer 134 except for the contact area CNT, deterioration such as a removal of the emitting layer 134 except for the contact area CNT is prevented.

In FIG. 7F, the second electrode 136 is formed on the emitting layer 134 by depositing a metallic material or a transparent conductive material. Since the second electrode 136 is disposed in the opening OPEN of the contact area CNT, the second electrode 136 is electrically connected to the side surfaces of the first and second conductive patterns 162 and 164 in the opening OPEN.

Next, the first encapsulating layer 182 is formed on the second electrode 136 by depositing an inorganic material. Next, the second encapsulating layer 184 is formed on the first encapsulating layer 182 by depositing an organic material. Next, the third encapsulating layer 186 is formed on the second encapsulating layer 184 by depositing an inorganic material to complete the encapsulating layer 180.

In a method of fabricating the display device 100 according to the first embodiment of the present disclosure, after the emitting layer 134 is formed on the conductive layer 164a in the contact area CNT, the conductive layer 164a and the emitting layer 134 in the opening OPEN of the contact area CNT are evaporated due to the heat by the laser. As a result, the second electrode 136 is electrically connected to the first and second conductive patterns 162 and 164 without an additional mask process for patterning the emitting layer 134 in the contact area CNT. Accordingly, a fabrication process is simplified and a fabrication cost is reduced.

The electric contact of the first conductive pattern 162 and the second electrode 136 in the contact area CNT can be obtained through various methods.

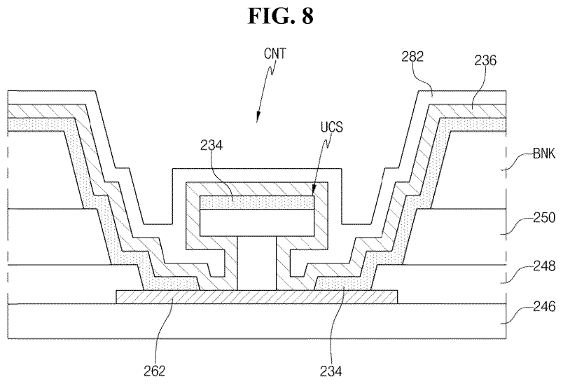

FIG. 8 is a cross-sectional view showing a contact area of a display device according to a second embodiment of the present disclosure.

In FIG. 8, a conductive pattern 262 is disposed on an interlayer insulating layer 246 in a contact area CNT. Portions of a first planarizing layer 248, a second planarizing layer 250 and a bank layer BNK over the conductive pattern 262 are removed such that the conductive pattern 262 is exposed through the first planarizing layer 248, the second planarizing layer 250 and the bank layer BNK. An undercut structure UCS or an overhang structure is disposed on the conductive pattern 262.

The undercut structure UCS can have a double layer formed by patterning the second planarizing layer 250 and the bank layer BNK or a triple layer formed by patterning the first planarizing layer 248, the second planarizing layer 250 and the bank layer BNK.

An emitting layer 234 is disposed on the conductive pattern 262. Since the emitting layer 234 includes an organic material having a relatively low step coverage, the emitting layer 234 is not disposed on the conductive pattern 262 under the undercut structure UCS. A second electrode 236 is disposed on the emitting layer 234. Since the second electrode 236 includes a metallic material having a relatively high step coverage, the second electrode 236 is disposed on top and side surfaces of the undercut structure UCS and on the conductive pattern 262 under the undercut structure UCS.

Since the emitting layer 234 is not disposed on a portion of the conductive pattern 262 due to the undercut structure UCS and the second electrode 236 is disposed on the portion of the conductive pattern 262 under the undercut structure UCS, the second electrode 236 is electrically connected to the conductive pattern 262.

Consequently, in the display device according to first and second embodiments of the present disclosure, since the plurality of layers in the contact area have step differences, the crack of the second electrode in the contact area is prevented and permeation of the moisture due to the crack is prevented.

Further, since an additional mask process for patterning the emitting layer in the contact area is omitted, the fabrication process is simplified and the fabrication cost is reduced in the display devices of the present embodiments.

In addition, according to the embodiments of the present disclosure, since the fabrication process is simplified, reduction of a product energy due to the process optimization is obtained.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display device comprising:
a substrate having a contact area and a display area including a plurality of subpixels;
a transistor in each of the plurality of subpixels in the display area;
a light emitting diode in each of the plurality of subpixels and including a first electrode, an emitting layer and a second electrode; and
a first conductive pattern having an opening in the contact area,
wherein the emitting layer extends to the first conductive pattern, and
wherein the second electrode extends to the first conductive pattern and is electrically connected to a side surface of the first conductive pattern in the opening of the first conductive pattern.

2. The display device of claim 1, wherein the transistor comprises:
a semiconductor layer in the display area;
a gate insulating layer on the semiconductor layer;
a gate electrode on the gate insulating layer;
an interlayer insulating layer on the gate electrode; and
a source electrode and a drain electrode on the interlayer insulating layer.

3. The display device of claim 2, wherein the first conductive pattern is disposed on the interlayer insulating layer and has a same material as the source and drain electrodes.

4. The display device of claim 3, further comprising a second conductive pattern on the first conductive pattern.

5. The display device of claim 4, wherein the second conductive pattern includes a transparent conductive material.

6. The display device of claim 5, wherein the second electrode is electrically connected to a side surface of the second conductive pattern in the opening of the first conductive pattern.

7. The display device of claim 2, further comprising:
a first planarizing layer on the transistor;
a connecting electrode on the first planarizing layer, the connecting electrode electrically connected to the drain electrode;
a second planarizing layer on the first planarizing layer, the second planarizing layer covering the connecting electrode; and
a bank layer on the second planarizing layer between adjacent two of the plurality of subpixels,
wherein the connecting electrode is electrically connected to the first electrode.

8. The display device of claim 7, wherein at least one of the second planarizing layer and the bank layer includes a photosensitive material having a black pigment.

9. The display device of claim 7, wherein the first conductive pattern includes a same material as the connecting electrode.

10. The display device of claim 7, wherein the first planarizing layer, the second planarizing layer and the bank layer have gradual step differences.

11. The display device of claim 5, wherein the second conductive pattern in the opening is removed with a laser.

12. The display device of claim 11, wherein the emitting layer in the opening is removed together with the second conductive pattern.
